(19) United States
(12) Patent Application Publication
(10) Pub. No.: US 2024/0332093 A1
(43) Pub. Date: Oct. 3, 2024

(54) CRITICAL DIMENSION PREDICTION SYSTEM AND OPERATION METHOD THEREOF

(71) Applicant: SAMSUNG ELECTRONICS CO., LTD., Suwon-si (KR)

(72) Inventors: In Seok PARK, Suwon-si (KR); WAN-SIK NAM, Suwon-si (KR); SOUK KIM, Suwon-si (KR); YOUNGHOON SOHN, Suwon-si (KR); JAEHYUNG AHN, Suwon-si (KR)

(73) Assignee: SAMSUNG ELECTRONICS CO., LTD., Suwon-si (KR)

(21) Appl. No.: 18/431,464

(22) Filed: Feb. 2, 2024

(30) Foreign Application Priority Data
Mar. 28, 2023 (KR) 10-2023-0040784

(51) Int. Cl. H01L 21/66

(52) U.S. Cl. CPC H01L 22/12

(57) ABSTRACT

A critical dimension prediction system includes a measuring device configured to acquire sample data from a sample semiconductor chip, the sample data including a plurality of spectrums, a training data selection device configured to select a training data set based on the sample data, a critical dimension predicting model generating device configured to generate a critical dimension predicting model by training an artificial intelligence model based on the training data set, and a critical dimension predicting device configured to predict a critical dimension of a target layer by inputting input data into the critical dimension predicting model, the input data including information about the target layer, where the training data selection device is further configured to assign a sparsity score to each of the plurality of spectrums and select at least one of the plurality of spectrums as the training data set based on the sparsity score.

### CROSS-REFERENCE TO RELATED APPLICATIONS

This application is based on and claims priority to Korean Patent Application No. 10-2023-0040784, filed on Mar. 28, 2023, in the Korean Intellectual Property Office, the disclosure of which is incorporated herein by reference in its entirety.

### BACKGROUND

One or more embodiments of the present disclosure relate to a critical dimension prediction system and operation method thereof, and more particularly, to a method of predicting a critical dimension through a critical dimension predicting model trained on a training data set selected from sample data.

In general, semiconductor devices may be manufactured through a deposition process forming a layer on a wafer, a photolithography process patterning the layer to form a pattern, and a cleaning process removing by-products generated during the photolithography process.

In recent years, as semiconductor devices have become highly integrated, a demand for accurately controlling semiconductor processes is emerging. To accurately control semiconductor processes, it is necessary to accurately predict process parameters such as a critical dimension of layers fabricated on a wafer.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a critical dimension prediction system having improved accuracy.

One or more example embodiments provide a critical dimension prediction system having high accuracy even with a small amount of sample data.

Additional aspects will be set forth in part in the description which follows and, in part, will be apparent from the description, or may be learned by practice of the presented embodiments.

According to an aspect of an example embodiment, a critical dimension prediction system may include a measuring device configured to acquire sample data from a sample semiconductor chip, the sample data including a plurality of spectrums, a training data selection device configured to select a training data set based on the sample data, a critical dimension predicting model generating device configured to generate a critical dimension predicting model by training an artificial intelligence model based on the training data set, and a critical dimension predicting device configured to predict a critical dimension of a target layer by inputting input data into the critical dimension predicting model, the input data including information about the target layer, where the training data selection device is further configured to assign a sparsity score to each of the plurality of spectrums and select at least one of the plurality of spectrums as the training data set based on the sparsity score, and the sparsity score indicates a sparsity of each of the plurality of spectrums in relation to a distribution of all spectrums.

According to an aspect of an example embodiment, a method of operating a critical dimension prediction system including a measuring device, a training data selection device, a critical dimension predicting model generating device, and a critical dimension predicting device, may include acquiring, with the measuring device, sample data from a sample semiconductor chip, the sample data including a plurality of spectrums, selecting, with the training data selection device, a training data set based on the sample data, generating, with the critical dimension predicting model generating device, a critical dimension predicting model by training an artificial intelligence model based on the training data set, and predicting, with the critical dimension predicting device, a critical dimension of a target layer by inputting input data into the critical dimension predicting model, the input data including information about the target layer, where the selecting of the training data set includes determining a sparsity score for each of the plurality of spectrums and selecting at least one of the plurality of spectrums as the training data set based on the sparsity score, and the sparsity score indicates a sparsity of each of the plurality of spectrums in relation to a distribution of all spectrums.

According to an aspect of an example embodiment, a training data selection device may include a data storage configured to receive, from a measuring device, sample data including a plurality of spectrums and store the sample data, a sparsity score calculating device configured to assign a sparsity score to each of the plurality of spectrums stored in the data storage, and a training data set extracting device configured to select, based on the sparsity score, at least one of the plurality of spectrums as a training data set for training a critical dimension predicting model, where the sparsity score indicates a sparsity of each of the plurality of spectrums in relation to a distribution of all spectrums.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a critical dimension prediction system, according to an embodiment of the present disclosure;

FIG. 2 is a diagram illustrating an example of a measuring device according to an embodiment of the present disclosure;

FIG. 3 is a flowchart illustrating an operation method of a critical dimension prediction system according to an embodiment of the present disclosure;

FIG. 4 is a diagram illustrating an example of a training data selection device according to an embodiment of the present disclosure;

FIG. 5 is a flowchart illustrating an operation method of a training data selection device according to an embodiment of the present disclosure;

FIG. 6 is a flowchart illustrating a method of assigning a first score according to an embodiment of the present disclosure;

FIG. 7 is a diagram illustrating operation S221 of FIG. 6 according to an embodiment of the present disclosure;

FIG. 8 is a diagram illustrating an example of a reconstruction loss deviation calculating device according to an embodiment of the present disclosure;

FIG. 9 is a diagram illustrating an auto-encoder according to an embodiment of the present disclosure; and

FIG. 10 is a flowchart illustrating operation S230 of FIG. 5 according to an embodiment of the present disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

As used herein, the terms “device” may refer to any combination of software, firmware, and/or hardware configured to provide the functionality described herein. For example, software may be implemented as a software package, code and/or set of instructions or instructions, and hardware may include hardwired circuitry, programmable circuitry, state machine circuitry, and/or a single or any combination, or assembly of firmware that stores instructions executed by programmable circuitry.

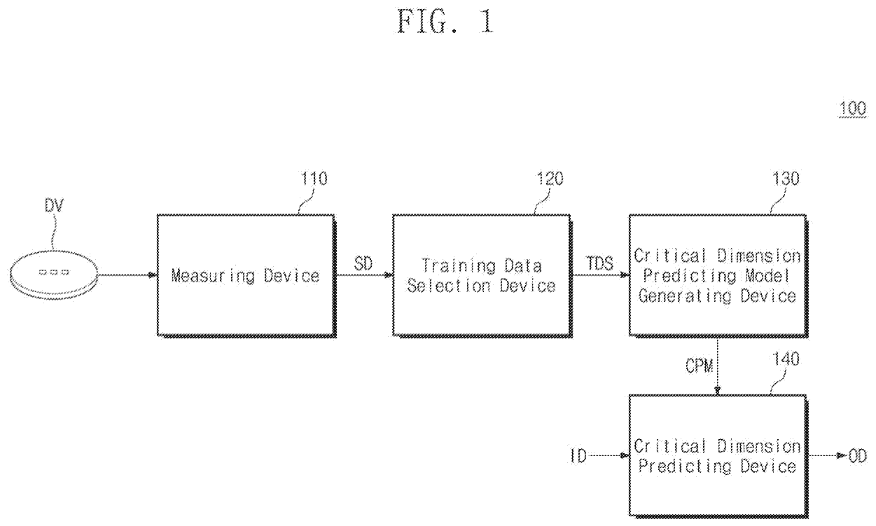

FIG. 1 is a diagram illustrating a critical dimension prediction system, according to an embodiment of the present disclosure.

Referring to FIG. 1, a critical dimension prediction system 100 may include a measuring device 110, a training data selection device 120, a critical dimension predicting model generating device 130, and a critical dimension predicting device 140.

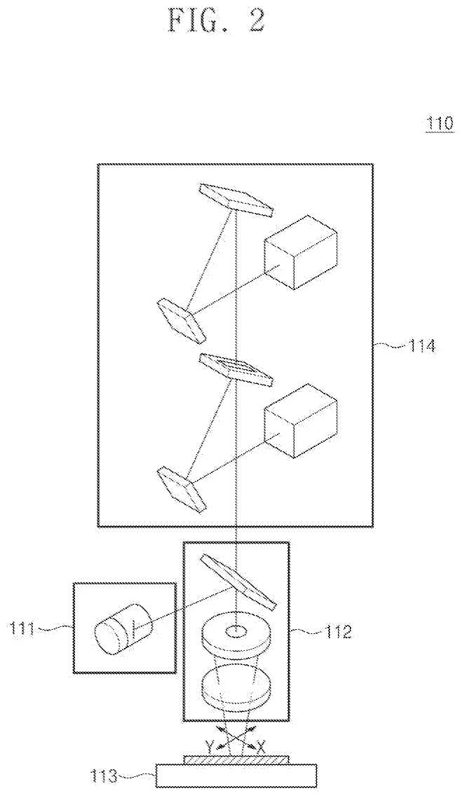

The measuring device 110 may be configured to acquire sample data SD from a sample semiconductor chip DV. The sample semiconductor chip DV may include, for example, layers including a plurality of conductive patterns and an insulating layer. The sample data SD may be acquired by measuring a critical dimension of each of layers constituting the sample semiconductor chip DV. A specific example of the measuring device 110 acquiring the sample data SD from the semiconductor chip DV will be described later with reference to FIG. 2.

The sample data SD may include a plurality of spectrums. For example, the sample data SD may include a plurality of optical critical dimension (OCD) spectrums.

In an embodiment, the plurality of spectrums may include information about optical critical dimensions of different wavelength bands in each of the layers constituting the semiconductor chip. For example, the plurality of spectrums may include a first spectrum including OCD information of a first wavelength band and a second spectrum including OCD information of a second wavelength band.

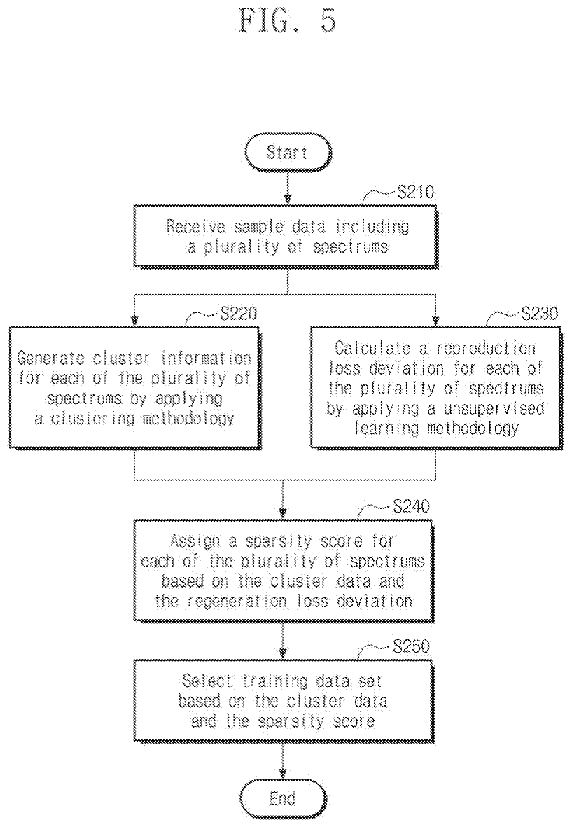

The training data selection device 120 may be configured to select a training data set TDS based on the sample data SD. The training data selection device 120 may be configured to determine a sparsity score for each of a plurality of spectrums of the sample data SD, and to select some of the plurality of spectrums as the training data set TDS based on the sparsity score. A detailed operation method of the training data selection device 120 will be described later with reference to FIGS. 5 to 10.

The sparsity score may be a value indicating how sparse each of the spectrums is in relation to a distribution of all spectrums. In an embodiment, the sparsity score may be associated with a probability that a specific spectrum is included in a region far from the mean of all spectrums by a predetermined distance, assuming that the distribution of all spectrums forms a normal distribution. For example, a specific spectrum may have a higher sparsity score when the specific spectrum is farther from the mean of all spectrums.

The training data set TDS selected by the training data selection device 120 may be provided to the critical dimension predicting model generating device 130.

The critical dimension predicting model generating device 130 may be configured to generate a critical dimension predicting model CPM by training an artificial intelligence model based on the training data set TDS. The critical dimension predicting model CPM may be used to predict the critical dimension of an input semiconductor layer.

In an embodiment, the artificial intelligence model may include a supervised learning model. For example, the artificial intelligence models include a K-Nearest Neibors (KNN), a Linear Regression, a Logistic Regression, a Support Vector Machines (SVM), a Decision Trees, a random forest, or a neural network algorithm model such as a convolutional neural network (CNN), a recurrent neural network (RNN), a support vector regression (SVR), etc.

The critical dimension predicting device 140 may be configured to generate output data OD by inputting input data ID to the critical dimension predicting model CPM generated by the critical dimension predicting model generating device 130. The input data ID may include, for example, information about a semiconductor layer (hereinafter referred to as a target layer) to be manufactured. The output data OD may include a predicted value of the critical dimension for the target layer. The critical dimension predicting device 140 may be configured to predict the critical dimension of the input target layer.

It may be required to secure a plurality of critical dimension spectrums so as to utilize a training model that predicts the critical dimension through OCD spectrums. However, securing a large amount of critical dimension spectrums may be time consuming, and there may be cost problems such as the cutting of manufactured semiconductor devices to secure critical dimension spectrums.

In particular, to secure initial training data associated with a new process, data should be extracted without background knowledge about the relationship between the OCD spectrum and the critical dimension of the corresponding process. In this case, methods of extracting spectrums are used by predicting two-dimensional distribution between OCD spectrums using methods such as a principal component analysis (PCA) or a t-distributed stochastic neighbor embedding (TSNE) that compresses from high-dimension to low-dimension using a random sampling or mean squared error information between measured OCDs and then by assuming that the predicted two-dimensional distribution will be similar to the distribution of the final target. Although these methods provide distribution information among the collected spectrums, it may be difficult to know how much a specific spectrum differs from the training set to be used for training. That is, it may be difficult to represent whether the training data set sufficiently includes information about other spectrums not included in training.

According to embodiments, the critical dimension of the target layer may be predicted with high accuracy even using a small amount of sample data. According to embodiments, securing a large amount of sample data may not be needed to improve the accuracy of the critical dimension prediction system, and since the number of semiconductor chips consumed for securing the sample data may be reduced, the manufacturing cost may be reduced.

According to embodiments, as the accuracy of predicting the critical dimension increases, the yield in the manufacturing process of the semiconductor chips may be improved. In the case of the present disclosure, a correlation between spectrums of sample data may be quantified, and an optimized training data set may be selected on this basis.

FIG. 2 is a diagram illustrating an example of a measuring device according to an embodiment of the present disclosure.

Referring to FIG. 2, the measuring device 110 may include a light source 111, an emitting device 112, a stage 113, and a spectrometer device 114. For example, the measuring device 110 may include an OCD measuring equipment that acquires sample data from a sample semiconductor chip.

The light source 111 may be configured to generate white light. The white light generated from the light source 111 may be emitted to the sample semiconductor chip placed on the stage 113 through the emitting device 112.

The spectrometer device 114 may be configured to detect reflected light reflected from the sample semiconductor chip. The spectrometer device 114 may be configured to measure an OCD of each spectrum by detecting reflected light for each spectrum. The OCD of each of the spectrums may be obtained as a mean value for the entire area of the sample semiconductor chip irradiated with light.

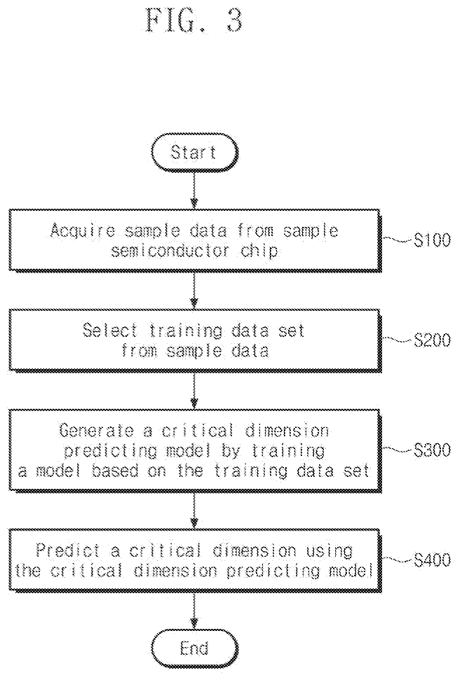

FIG. 3 is a flowchart illustrating an operation method of a critical dimension prediction system according to an embodiment of the present disclosure. Hereinafter, referring to FIG. 1 together, a method of operating the critical dimension prediction system will be described.

Referring to FIGS. 1 and 3, in operation S100, the measuring device 110 may acquire the sample data SD from the sample semiconductor chip DV. The sample data SD may include a plurality of spectrums. For example, the plurality of spectrums may include information about OCDs of different wavelength bands in each of the layers constituting the semiconductor chip.

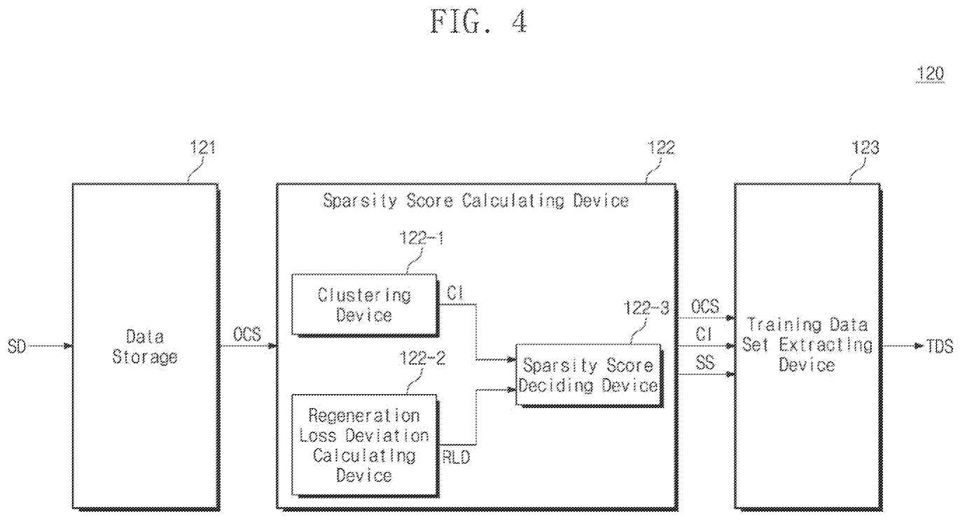

In operation S200, the training data selection device 120 may select the training data set TDS based on the sample data SD. The training data selection device 120 may determine a sparsity score for each of a plurality of spectrums of the sample data SD, and may select some of the plurality of spectrums as the training data set TDS based on the sparsity score. A specific method of selecting the training data set TDS will be described later with reference to FIGS. 4 to 10.

In operation S300, the critical dimension predicting model generating device 130 may generate the critical dimension predicting model CPM by training an artificial intelligence model based on the training data set TDS. In an embodiment, the artificial intelligence model may include a supervised learning model. The critical dimension predicting model CPM may be used to predict the critical dimension of an input target layer.

In operation S400, the critical dimension predicting device 140 may predict a critical dimension of the input target layer using the critical dimension predicting model CPM.

FIG. 4 is a diagram illustrating an example of a training data selection device according to an embodiment of the present disclosure.

Referring to FIG. 4, the training data selection device 120 may include a data storage 121, a sparsity score calculating device 122, and a training data set extracting device 123.

The data storage 121 may be configured to receive the sample data SD from the measuring device 110 of FIG. 1. The data storage 121 may be configured to store a plurality of spectrums OCS of the received sample data SD.

The sparsity score calculating device 122 may include a clustering device 122-1, a reconstruction loss deviation calculating device 122-2, and a sparsity score deciding device 122-3. The sparsity score calculating device 122 may be configured to determine a sparsity score SS for the plurality of spectrums OCS stored in the data storage 121.

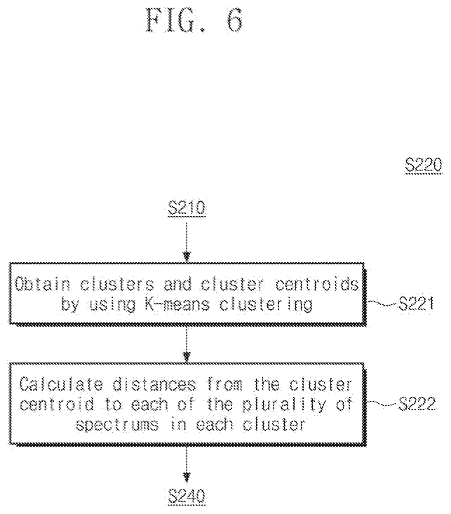

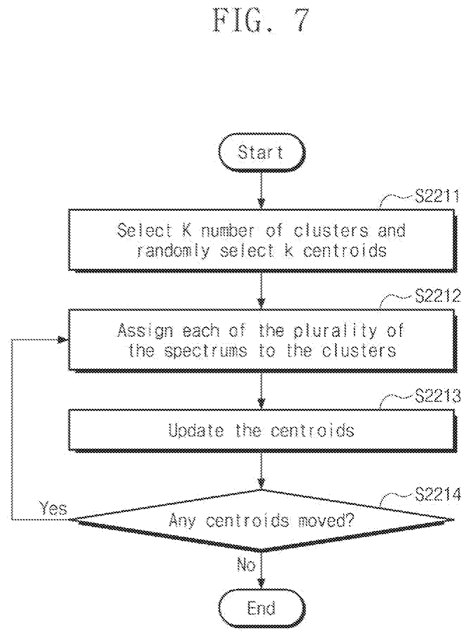

The clustering device 122-1 may be configured to generate cluster information CI for each of the plurality of spectrums OCS by applying a clustering methodology (e.g., a clustering process) to the plurality of spectrums OCS. The cluster information CI may include information about a cluster to which each of the plurality of spectrums OCS belongs and cluster centroids. A detailed operation of the clustering device 122-1 will be described later with reference to FIGS. 6 and 7.

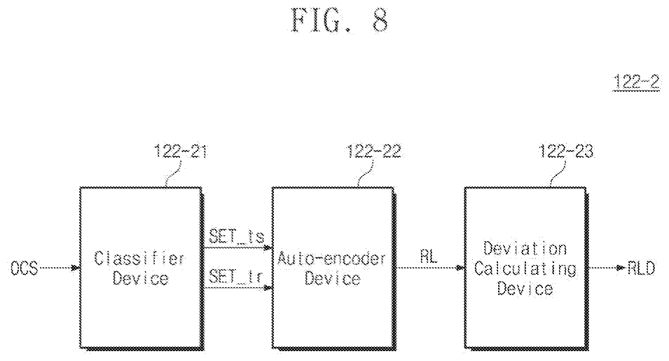

The reconstruction loss deviation calculating device 122-2 may be configured to calculate a reconstruction loss deviation RLD for each of the plurality of spectrums by applying an unsupervised learning methodology (e.g., unsupervised learning process) to the plurality of spectrums OCS. The detail configuration and operation of the reconstruction loss deviation calculating device 122-2 will be described later with reference to FIGS. 8 to 10.

The sparsity score deciding device 122-3 may be configured to determine the sparsity score SS based on the cluster information CI and the reconstruction loss variance RLD for each of the plurality of spectrums OCS. In an embodiment, the sparsity score deciding device 122-3 may be configured to assign a first score for each of the plurality of spectrums OCS based on the cluster information CI, and to assign a second score for each of the plurality of spectrums OCS based on the reconstruction loss deviation RLD. In an embodiment, the sparsity score deciding device 122-3 may be configured to determine the sparsity score SS for each of the plurality of spectrums OCS based on the first score and the second score.

The sparsity score SS determined for each of the plurality of spectrums OCS may be related to a distance from the mean of the plurality of spectrums. For example, in the case of a spectrum for which a lower sparsity score SS is determined, the spectrum may be located closer to the population mean than a spectrum for which a higher sparsity score SS is determined.

The training data set extracting device 123 may be configured to select the training data set TDS based on the sparsity score SS for each of the plurality of spectrums OCS determined by the sparsity score deciding device 122-3. The training data set TDS may be acquired by selecting a specific number of spectrums from among the plurality of spectrums OCS.

In an embodiment, the training data set extracting device 123 may select the specific number of spectrums from among the plurality of spectrums OCS in order of low sparsity scores SS as the training data set TDS. In another embodiment, the training data set extracting device 123 may select the specific number of spectrums from among the plurality of spectrums OCS in order of high sparsity scores SS as the training data set TDS.

FIG. 5 is a flowchart illustrating an operation method of a training data selection device according to an embodiment of the present disclosure.

Referring to FIGS. 4 and 5, in operation S210, the data storage 121 may receive the sample data SD from the measuring device 110 of FIG. 1. The sample data SD may include the plurality of spectrums OCS.

In operation S220, the clustering device 122-1 may generate the cluster information CI for each of the plurality of spectrums OCS by applying the clustering methodology to the plurality of spectrums OCS. In an embodiment, the cluster methodology may include K-means clustering.

The cluster information CI of each of the plurality of spectrums OCS may include information about a cluster to which the spectrum belongs and centroids of the cluster. A detailed description of acquiring the cluster information CI for each of the plurality of spectrums OCS will be described later with reference to FIGS. 6 and 7.

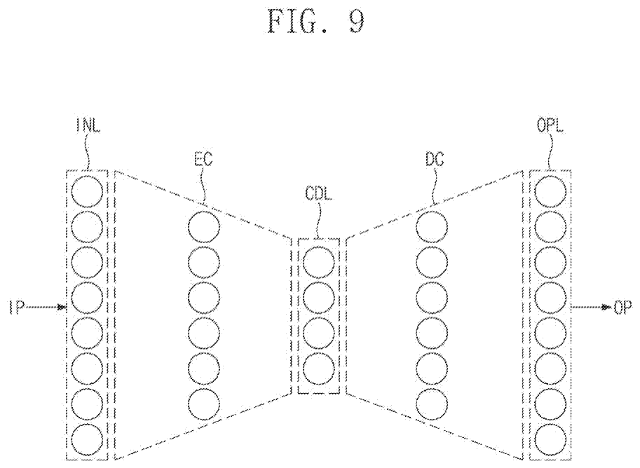

In operation S230, the reconstruction loss deviation calculating device 122-2 may calculate the reconstruction loss deviation RLD for each of the plurality of spectrums OCS by applying the unsupervised learning methodology to the plurality of spectrums OCS. In an embodiment, the unsupervised learning methodology may include an auto-encoder. Details of calculating the reconstruction loss deviation RLD for each of the plurality of spectrums OCS will be described later with reference to FIGS. 8 and 9.

In an embodiment, operation S220 may be performed before operation S230. In another embodiment, operations S220 and S230 may be performed simultaneously. In another embodiment, operation S230 may be performed before operation S220. After all operations S220 and S230 are performed, operation S240 may be performed.

In operation S240, the sparsity score deciding device 122-3 may assign a first score for each of the plurality of spectrums OCS based on the cluster information CI, and may assign a second score for each of the plurality of spectrums OCS based on the reconstruction loss deviation RLD. The sparsity score deciding device 122-3 may determine the sparsity score of each of the plurality of spectrums OCS based on the first score and the second score.

For example, the sparsity score for the i-th spectrum (‘i’ is a natural number greater than or equal to ‘1’) may be calculated according to Equation (1).

$${s}_{i} = α {\overline{d}}_{i} + ( 1 - α ) {\overline{σ}}_{i} , \qquad ( 1 )$$

$$α ∈ [ 0 , 1 ]$$

d̅ᵢ is the first score for the i-th spectrum, σ̅ᵢ is the second score for the i-th spectrum, and sᵢ is the sparse score for the i-th spectrum.

When calculating the sparsity score, the value of ‘α’ may be set depending on a weight of the first score and the second score. For example, when a higher weight is given to the first score in the sparsity score, the value of ‘α’ may be set to a range between 0.5 and 1. As another example, when a high weight is given to the second score in the sparsity score, the value of ‘α’ may be set to a range between 0 and 0.5. As another example, when the same weight is given to the first score and the second score, the value of ‘α’ may be set to 0.5.

Through operations S220 to S240, the sparsity score calculating device 122 may determine the sparsity score SS for each of the plurality of spectrums OCS stored in the data storage 121.

In operation S250, the training data set extracting device 123 may select the training data set TDS based on the cluster information CI and the sparsity score SS for each of the plurality of spectrums OCS. The training data set extracting device 123 may extract a specific number of spectrums from among the plurality of spectrums OCS based on the sparsity score and may select the extracted spectrums as the training data set TDS.

In an embodiment, based on the sparsity score, the specific number of spectrums from among the plurality of spectrums OCS may be selected as the training data set TDS. For example, as in Equation (2), all of the plurality of spectrums OCS may be sorted in descending order according to the sparsity score.

$${\overline{s}}_{1} = max ( S ) \geq {\overline{s}}_{2} \geq … \geq {\overline{s}}_{r} = min ( S ) \qquad ( 2 )$$

In Equation (2), S denotes a set of all of the plurality of spectrums OCS, max(S) denotes the highest sparsity score among all sparsity scores of the plurality of spectrums OCS, and min(S) denotes the lowest sparsity score among all sparsity scores of the plurality of spectrums OCS.

As illustrated in Equation (3), among the sorted sparsity scores, the specific number of spectrums may be selected as the training data set TDS in the order of low sparsity scores.

$${X}_{f} = {⋃}_{i = 1}^{{N}_{f}} x ( {\overline{s}}_{r + 1 - i} ) \qquad ( 3 )$$

In Equation (3), N_{f} is the number of spectrums to be selected as the training data set TDS, and x (s̅ᵣ₊₁₋ᵢ) denotes a spectrum corresponding to a sparsity score s̅ᵣ₊₁₋ᵢ. In an embodiment, spectrums of the selected training data set TDS may be selected as spectrums close to the population mean.

In another embodiment, the training data set extracting device 123 may select a specific number of spectrums from each cluster as the training data set TDS based on the cluster information CI and the sparsity score. For example, as illustrated in Equation (4), the number of spectrums to be selected for each cluster may be determined based on the mean distance (d_{avg}^{k}, k∈[1, 2, . . . , K]) from the centroids of the spectrums in each of the K number of clusters (C_{avg}^{k}, k∈[1, 2, . . . , K]).

$${N}_{1} = [ {r}_{1} {N}_{c} ] , \qquad ( 4 )$$

$${N}_{i} = [ {N}_{c} {\sum }_{j = 1}^{i} {r}_{j} ] - [ {N}_{c} {\sum }_{j = 1}^{i - 1} {r}_{j} ] ,$$

$$i ∈ \{ 2 , 3 , … , K \}$$

In Equation (4), Nᵢ is the number of spectrums to be selected in the i-th cluster, └x┘ is a floor function that outputs the largest integer less than or equal to x, N_{c} is the number of the total number Xₑ of selected spectrums OCS, and K is the number of the clusters. rᵢ is a ratio of the mean distance of the i-th cluster to the sum of the mean distances of K number of clusters, as determined in Equation (5).

$${r}_{i} = \frac{{d}_{avg}^{i}}{{\sum }_{k = 1}^{K} {d}_{avg}^{k}} , \qquad ( 5 )$$

$$i ∈ \{ 1 , 2 , … , K \}$$

Subsequently, as illustrated in Equation (6) below, among the spectrums belonging to each cluster, the training data set TDS (X_{c}) may be selected in the order of high sparsity score.

$${X}_{c} = {⋃}_{k = 1}^{K} {⋃}_{i = 1}^{{N}_{k}} \{ x ( {\overline{s}}_{i}^{k} ) \} , \qquad ( 6 )$$

$$where$$

$${\overline{s}}_{i}^{k} = max ( {S}^{k} ) \geq {\overline{s}}_{2}^{k} \geq … \geq {\overline{s}}_{n ( {c}_{k} )} = min ( {S}^{k} )$$

In the case of an embodiment, as the selected training data set TDS, spectrums distant from the centroid of each cluster may be selected.

FIG. 6 is a flowchart illustrating a method of assigning a first score according to an embodiment of the present disclosure. FIG. 7 is a diagram illustrating operation S221 of FIG. 6 according to an embodiment of the present disclosure.

Referring to FIGS. 4 and 6, in operation S221, the clustering device 122-1 may generate K number of clusters and K number of cluster centroids by applying K-Means clustering to the plurality of spectrums OCS. Hereinafter, with reference to FIG. 7 together, application of the K-means clustering to the plurality of spectrums OCS will be described in detail.

Referring to FIG. 7 together, in operation S2211, the clustering device 122-1 may select K number of clusters and may select K cluster centroids as initial values. In operation S2212, the clustering device 122-1 may assign each of the spectrums to the cluster corresponding to the closest centroid. In operation S2213, the clustering device 122-1 may update the cluster centroids based on the spectrum assigned to each cluster. For example, the clustering device 122-1 may update the cluster centroids such that the mean distance from the cluster centroids to the spectrums is minimized. In operation S2214, when the cluster centroid is moved, the clustering device 122-1 may return to operation S2212 and perform operations S2212 and S2213 again. In operation S2214, when the cluster centroid is not moved, the clustering device 122-1 may end the clustering.

Referring back to FIG. 6, in operation S222, the clustering device 122-1 may calculate distances from the cluster centroid of the cluster to which the spectrums belong, for each of the plurality of spectrums OCS. For example, the distance between the spectrum and the cluster centroid may be calculated through a mean square error (MSE) function.

In operation S240, the sparsity score deciding device 122-3 may assign a first score for each of the plurality of spectrums OCS based on the distance from the cluster centroid.

In an embodiment, the first score may be given higher as the distance from the spectrum and the cluster centroid increases. For example, when the distance from the cluster centroid of the first spectrum is greater than the distance from the cluster centroid of the second spectrum, the first score of the first spectrum may be higher than the first score of the second spectrum.

FIG. 8 is a diagram illustrating an example of a reconstruction loss deviation calculating device according to an embodiment of the present disclosure. FIG. 9 is a diagram illustrating an auto-encoder according to an embodiment of the present disclosure.

Referring to FIGS. 4 and 8, the reconstruction loss deviation calculating device 122-2 may include a classifier 122-21, an auto-encoder 122-22, and a deviation calculating device 122-23.

The classifier 122-21 may be configured to classify the plurality of spectrums OCS of the sample data SD into a training set SET_ts and a test set SET_tr. In an embodiment, the classifier 122-21 may be configured to classify some of the plurality of spectrums OCS of the sample data SD into the training set SET_ts and to classify the remaining parts into the test set SET_tr. The training set SET_ts may be a set for training the auto-encoder 122-22, and the test set SET_tr may be a set for acquiring the reconstruction loss from the trained auto-encoders 122-22. For example, the classifier 122-21 may be configured to randomly classify the plurality of spectrums OCS into the training set SET_ts and the test set SET_tr.

The auto-encoder 122-22 may be configured to be trained based on the spectrums classified into the training set SET_ts. Thereafter, by inputting the spectrums classified into the test set SET_tr in the auto-encoder 122-22, the reconstruction loss for each spectrum of the test set SET_tr may be obtained.

Referring to FIG. 9 together, the auto-encoder 122-22 may include an input layer INL, an encoder EC, a coding layer CDL, a decoder DC, and an output layer OPL.

The input layer INL may be composed of a plurality of neurons (nodes) to receive an input IP. In the process of training the auto-encoder 122-22, the input IP may be the spectrums of the training set SET_ts. The number of neurons of the input layer INL may be the same as the number of dimensions of the input IP.

The encoder EC may include at least one hidden layer, and may be configured to output feature data by reducing the dimension of the input IP. The number of neurons constituting each hidden layer constituting the encoder EC may be equal to, greater than, or less than the number of neurons constituting the input layer INL.

The coding layer CDL may be configured to receive feature data according to dimension reduction of the encoder EC. Data applied to the coding layer CDL may become data obtained by reducing the dimension of the input IP by the encoder EC.

The decoder DC may be configured to output an output OP obtained by regenerating the input IP using the feature data transferred to the coding layer CDL. The decoder DC may include at least one hidden layer.

The decoder DC may be configured to have the same structure as the encoder EC, and training may be performed such that the weights (parameters) of the encoder EC and the decoder DC are the same.

The output layer OPL may include the same number of neurons as the input layer INL and may be configured to output the output OP modeled similarly to the input IP.

When the input IP goes through the encoder EC and the decoder DC, the function of the auto-encoder 122-22 is to ensure that the features of the input IP can be well extracted by training to make the input IP and output OP as similar as possible.

In this way, the auto-encoder 122-22 may be a neural network that equalizes the input IP and the output OP, makes the number of dimensions of the input IP input to the input layer INL of the encoder EC and the output OP output from the output layer OPL the same, and allows the coding layer CDL to represent the input IP in a dimension less than that of the input layer INL and the output layer OPL.

The reconstruction loss RL may be a measure of how accurately the auto-encoder can regenerate the input. This reconstruction loss may be measured by calculating the difference between the input IP and the output OP generated by the auto-encoder.

For example, the reconstruction loss RL may be obtained by calculating the square error between input data and output data generated by the model through the MSE function. As another example, the reconstruction loss RL may be obtained by using other loss functions such as a root mean squared error (RMSE), a cross-entropy loss, etc.

Referring back to FIG. 8, the deviation calculating device 122-23 may be configured to calculate the reconstruction loss deviation RLD based on the reconstruction loss RL for each of the plurality of spectrums. For example, the reconstruction loss deviation RLD may be a standard deviation with respect to a plurality of reconstruction losses RL for each of the plurality of spectrums.

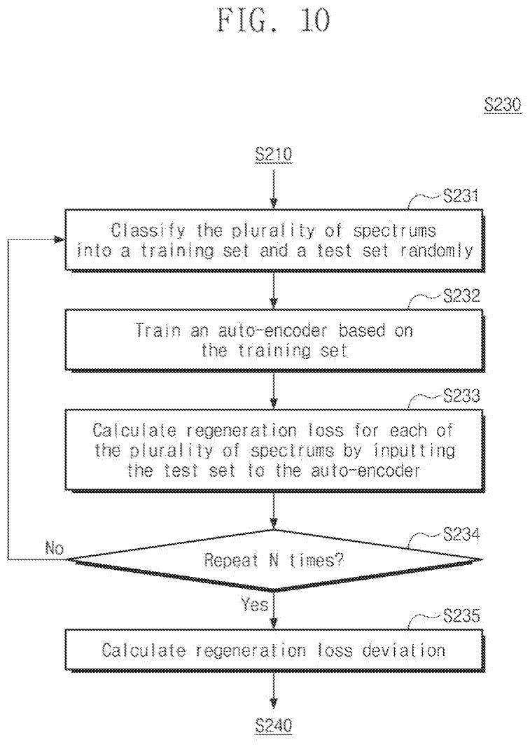

FIG. 10 is a flowchart illustrating operation S230 of FIG. 5 according to an embodiment of the present disclosure. Hereinafter, the operation of the reconstruction loss deviation calculating device 122-2 will be described in detail with reference to FIGS. 8 and 9 together.

Referring to FIGS. 8 and 10, in operation S231, the classifier 122-21 may divide the plurality of spectrums OCS of the sample data SD into the training set SET_ts and the test set SET_tr. In an embodiment, the classifier 122-21 may classify some of the plurality of spectrums OCS of the sample data SD into the training set SET_ts and may classify the remaining parts into the test set SET_tr.

In operation S232, the reconstruction loss deviation calculating unit 122-2 may train the auto-encoder 122-22 based on the training set SET_ts.

In operation S233, the reconstruction loss deviation calculating device 122-2 may calculate the reconstruction loss for each spectrum of the test set SET_tr by inputting the test set SET_tr to the trained auto-encoder 122-22.

In operation S234, the deviation calculating device 122-23 may determine whether operations S231 to S233 are repeated N times. For example, ‘N’ may be greater than the total number of spectrums. For example, when operations S231 to S233 are repeated N times, the deviation calculating device 122-23 may obtain at least three or more reconstruction losses for each of the plurality of spectrums OCS. When operations S231 to S233 are repeated N times, operation S235 may be performed.

In operation S235, the deviation calculating device 122-23 may calculate the reconstruction loss deviation for each of the plurality of spectrums OCS. For example, a first reconstruction loss deviation for a plurality of reconstruction losses of the first spectrum and a second reconstruction loss deviation for a plurality of reconstruction losses of the second spectrum may be calculated.

In operation S240, the sparsity score deciding device 122-3 may determine a second score of each of the plurality of spectrums OCS based on the reconstruction loss deviation. In an embodiment, the second score may be given higher as the reconstruction loss deviation increases. For example, when the first reconstruction loss deviation of the first spectrum is greater than the second reconstruction loss deviation of the second spectrum, the second score of the first spectrum may be greater than the second score of the second spectrum.

According to an embodiment of the present disclosure, a critical dimension prediction system having improved accuracy is provided.

According to an embodiment of the present disclosure, a critical dimension prediction system having high accuracy with a small amount of sample data is provided.

At least one of the devices, units, components, modules, units, or the like represented by a block or an equivalent indication in the above embodiments including FIGS. 1, 4 and 8 may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein). Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A critical dimension prediction system comprising:
a measuring device configured to acquire sample data from a sample semiconductor chip, the sample data comprising a plurality of spectrums;
a training data selection device configured to select a training data set based on the sample data;
a critical dimension predicting model generating device configured to generate a critical dimension predicting model by training an artificial intelligence model based on the training data set; and
a critical dimension predicting device configured to predict a critical dimension of a target layer by inputting input data into the critical dimension predicting model, the input data comprising information about the target layer,
wherein the training data selection device is further configured to:
assign a sparsity score to each of the plurality of spectrums, and
select at least one of the plurality of spectrums as the training data set based on the sparsity score, and
wherein the sparsity score indicates a sparsity of each of the plurality of spectrums in relation to a distribution of all spectrums.

2. The critical dimension prediction system of claim 1, wherein the training data selection device comprises:
a data storage configured to receive the sample data from the measuring device and to store the sample data;
a sparsity score calculating device configured to assign the sparsity score to the plurality of spectrums stored in the data storage; and
a training data set extracting device configured to select the at least one of the plurality of spectrums as the training data set based on the sparsity score.

3. The critical dimension prediction system of claim 2, wherein the sparsity score calculating device comprises:
a clustering device configured to generate cluster information about each of the plurality of spectrums by applying a clustering process to the plurality of spectrums;
a reconstruction loss deviation calculating device configured to calculate a reconstruction loss deviation for each of the plurality of spectrums by applying an unsupervised learning process to the plurality of spectrums; and
a sparsity score deciding device configured to determine the sparsity score based on the cluster information and the reconstruction loss deviation for each of the plurality of spectrums.

4. The critical dimension prediction system of claim 3, wherein the clustering device is further configured to generate the cluster information by applying K-Means clustering to the plurality of spectrums, the cluster information comprising K number of clusters and K number of cluster centroids.

5. The critical dimension prediction system of claim 4, wherein the clustering device is further configured to calculate, for each of the plurality of spectrums, a distance from a cluster centroid of a cluster to which each corresponding spectrum of the plurality of spectrums belongs.

6. The critical dimension prediction system of claim 4, wherein the reconstruction loss deviation calculating device comprises:
a classifier device configured to classify the plurality of spectrums into a training set and a test set;
an auto-encoder device configured to be trained based on the training set and to receive the test set to calculate a reconstruction loss for each of the spectrums in the test set; and
a deviation calculating device configured to calculate the reconstruction loss deviation for each of the plurality of spectrums based on the reconstruction loss.

7. The critical dimension prediction system of claim 6, wherein the sparsity score deciding device is further configured to:
assign a first score to each of the plurality of spectrums based on a distance from a cluster centroid;
assign a second score to each of the plurality of spectrums based on the reconstruction loss deviation; and
determine the sparsity score based on the first score and the second score.

8. The critical dimension prediction system of claim 7, wherein the first score increases as the distance from the cluster centroid increases.

9. The critical dimension prediction system of claim 7, wherein the second score increases as the reconstruction loss deviation increases.

10. The critical dimension prediction system of claim 7, wherein the training data set extracting device is further configured to select, as the training data set, a number of spectrums in order of low sparsity scores among the plurality of spectrums.

11. A method of operating a critical dimension prediction system comprising a measuring device, a training data selection device, a critical dimension predicting model generating device, and a critical dimension predicting device, the method comprising:
acquiring, with the measuring device, sample data from a sample semiconductor chip, the sample data comprising a plurality of spectrums;
selecting, with the training data selection device, a training data set based on the sample data;
generating, with the critical dimension predicting model generating device, a critical dimension predicting model by training an artificial intelligence model based on the training data set; and
predicting, with the critical dimension predicting device, a critical dimension of a target layer by inputting input data into the critical dimension predicting model, the input data comprising information about the target layer,
wherein the selecting of the training data set comprises:
determining a sparsity score for each of the plurality of spectrums; and
selecting at least one of the plurality of spectrums as the training data set based on the sparsity score, and
wherein the sparsity score indicates a sparsity of each of the plurality of spectrums in relation to a distribution of all spectrums.

12. The method of claim 11, wherein the determining of the sparsity score comprises:
generating cluster information about each of the plurality of spectrums by applying a clustering process to the plurality of spectrums;
calculating a reconstruction loss deviation for each of the plurality of spectrums by applying an unsupervised learning process to the plurality of spectrums; and
determining the sparsity score based on the cluster information and the reconstruction loss deviation for each of the plurality of spectrums.

13. The method of claim 12, wherein the generating of the cluster information comprises generating the cluster information by applying K-Means clustering to the plurality of spectrums, the cluster information comprising K number of clusters and K number of cluster centroids.

14. The method of claim 13, wherein the generating of the cluster information further comprises calculating, for each of the plurality of spectrums, a distance from a cluster centroid of a cluster to which the spectrum belongs.

15. The method of claim 14, wherein the calculating of the reconstruction loss deviation comprises:
classifying the plurality of spectrums into a training set and a test set;
acquiring a reconstruction loss for each of the spectrums of the test set by training an auto-encoder based on the training set and inputting the test set into the trained auto-encoder; and
calculating the reconstruction loss deviation for each of the plurality of spectrums based on the reconstruction loss.

16. A training data selection device comprising:
a data storage configured to:
receive, from a measuring device, sample data comprising a plurality of spectrums; and
store the sample data;
a sparsity score calculating device configured to assign a sparsity score to each of the plurality of spectrums stored in the data storage; and
a training data set extracting device configured to select, based on the sparsity score, at least one of the plurality of spectrums as a training data set for training a critical dimension predicting model,
wherein the sparsity score indicates a sparsity of each of the plurality of spectrums in relation to a distribution of all spectrums.

17. The training data selection device of claim 16, wherein the sparsity score calculating device comprises:
a clustering device configured to generate cluster information about each of the plurality of spectrums by applying a clustering process to the plurality of spectrums;
a reconstruction loss deviation calculating device configured to calculate a reconstruction loss deviation for each of the plurality of spectrums by applying an unsupervised learning process to the plurality of spectrums; and
a sparsity score deciding device configured to determine the sparsity score based on the cluster information and the reconstruction loss deviation for each of the plurality of spectrums.

18. The training data selection device of claim 17, wherein the clustering device is further configured to generate the cluster information by applying K-Means clustering to the plurality of spectrums, the cluster information comprising K number of clusters and K number of cluster centroids.

19. The training data selection device of claim 18, wherein the reconstruction loss deviation calculating device comprises:
a classifier device configured to classify the plurality of spectrums into a training set and a test set;
an auto-encoder device configured to be trained based the training set and to receive the test set to calculate a reconstruction loss for each of the spectrums in the test set; and
a deviation calculating device configured to calculate the reconstruction loss deviation for each of the plurality of spectrums based on the reconstruction loss.

20. The training data selection device of claim 19, wherein the sparsity score deciding device is further configured to:
assign a first score to each of the plurality of spectrums based on a distance from a cluster centroid;
assign a second score to each of the plurality of spectrums based on the reconstruction loss deviation; and
determine the sparsity score based on the first score and the second score.
